(19) United States
(12) Patent Application Publication
(10) Pub. No.: US 2008/0150081 A1
(43) Pub. Date: Jun. 26, 2008

(54) Semiconductor device

(75) Inventors: Kati Kuusisto, Tampere (FI); Petri Juhani Korpi, Kangasala (FI)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(73) Assignee: Nokia Corporation

(21) Appl. No.: 11/645,212

(22) Filed: Dec. 22, 2006

(51) Int. Cl. H01L 29/70; H01L 21/331

(52) U.S. Cl. 257/565; 438/311; 438/378; 257/E21.37; 257/E29.171

(57) ABSTRACT

A method comprising providing a substrate and forming a device on the substrate, wherein forming the device includes printing at least one region of inorganic semiconductor on the substrate.

### FIELD OF THE INVENTION

The present invention relates to semiconductor devices, particularly, but not exclusively, to bipolar transistors.

### BACKGROUND ART

Bipolar junction transistors can be fabricated using well-known deposition and patterning processes, such as chemical vapour deposition (CVD), photolithography and dry etching. These processes yield good quality transistors having high mobilities (e.g. >100 cm²V⁻¹ s⁻¹) suitable for radio frequency applications. However, these processes tend to use expensive fabrication facilities and to be inflexible because, for example, they require the use of semiconductor substrates.

The present invention seeks to provide an alternative method of fabricating a semiconductor device, such as a bipolar transistor.

### SUMMARY

According to a first aspect of the present invention there is provided a method comprising providing a substrate and forming a bipolar transistor on the substrate, wherein forming the device includes printing at least one region of inorganic semiconductor on the substrate.

Thus, a bipolar transistor can be formed on a wider variety of substrates using a process which can be more flexible and cheaper to implement than existing processes.

The method may further comprise heating the region of inorganic semiconductor and allowing the region to cool so that at least a portion of the region of the inorganic semiconductor crystallizes. Heating the region of inorganic semiconductor may comprise scanning a laser beam over the region of inorganic semiconductor.

Thus, the inorganic semiconductor may crystallize, for example, to form a polycrystalline semiconductor which may have a higher mobility.

The method may further comprise removing a portion of the region of inorganic semiconductor. Removing the portion of the region of inorganic semiconductor may comprise scanning a laser beam over the inorganic semiconductor.

Thus, the at least one region can be printed with a wider tolerance, while critical device dimensions (such as gate length) can be defined within narrower tolerances.

Forming the semiconductor device may comprise printing a first region of an inorganic semiconductor of a first conductivity type and printing a second region of an inorganic semiconductor of a second, different conductivity type.

The substrate may comprise glass or plastic.

The method may further comprise processing the substrate before printing the at least one region of inorganic semiconductor on the substrate. Processing the substrate may comprise etching the substrate. Processing the substrate may comprise providing a layer on the substrate and printing the at least one region of inorganic semiconductor over at least a portion of the layer.

The inorganic semiconductor may comprise silicon. The inorganic semiconductor may be silicon or silicon-germanium.

According to a second aspect of the present invention there is provided a method comprising providing a substrate and forming a semiconductor device on the substrate, wherein forming the semiconductor device includes printing at least one region of inorganic semiconductor on the substrate and heating the at least one region of inorganic semiconductor and allowing the at least one region to cool so that at least a portion of an inorganic semiconductor region crystallizes.

This can improve performance (e.g. mobility) of a semiconductor device having a region of inorganic semiconductor formed by printing.

According to a third aspect of the present invention there is provided a device comprising a bipolar transistor having at least one region comprising an inorganic semiconductor, the region formed by printing.

The region may be identified as having been formed by printing by analysing the semiconductor region to find traces of carrier and/or uncured ink, for example using secondary ion mass spectroscopy, and/or to identify a structure characteristic of printed inks (e.g. edge profile, distribution of crystal size) using, for example scanning electron microscopy. Additionally or alternatively, inferring printing from context, such as type of substrate used.

Thus, even though the region may have subsequently been processed (e.g. cured), the region may be identified as having been formed by printing.

The inorganic semiconductor may comprise silicon and the substrate may comprise glass or plastic. The device may comprise substrate having a trench and the at least one region comprising the inorganic semiconductor may be disposed within the trench. The bipolar transistor may comprise an emitter, a base and a collector region, and each region comprises an inorganic semiconductor formed by printing.

### BRIEF DESCRIPTION OF THE DRAWINGS

Embodiments of the present invention will now be described, by way of example, with reference to the accompanying drawings in which:

FIG. 1 is a plan view of a bipolar junction transistor fabricated using a method according to certain embodiments of the present invention;

FIG. 2 is a cross-sectional view of the bipolar junction transistor shown in FIG. 1 taken along a line A-A′;

FIGS. 3a to 3h are cross-sectional views of the bipolar junction transistor shown in FIG. 1 at different stages during fabrication;

FIGS. 4a and 4b are plan views of the bipolar junction transistor shown in FIG. 1 at two different stages during fabrication;

FIG. 5 is a schematic block diagram of a fabrication apparatus;

FIGS. 6a and 6b are plan views of a bipolar junction transistor shown in FIG. 1 at two different stages during fabrication using an alternative approach;

FIGS. 7a to 7h are cross-sectional views of another bipolar junction transistor at different stages during fabrication;

FIGS. 8a to 8h are cross-sectional views of yet another bipolar junction transistor at different stages during fabrication;

FIG. 9 is a plan view of a differential pair bipolar junction transistor fabricated using a method according to certain embodiments of the present invention;

FIG. 10 is a cross-sectional view of still another bipolar junction transistor; and

FIG. 11 is a cross-sectional view of a hetero bipolar transistor (HBT).

### DETAILED DESCRIPTION OF PREFERRED EMBODIMENTS

### Device Structure

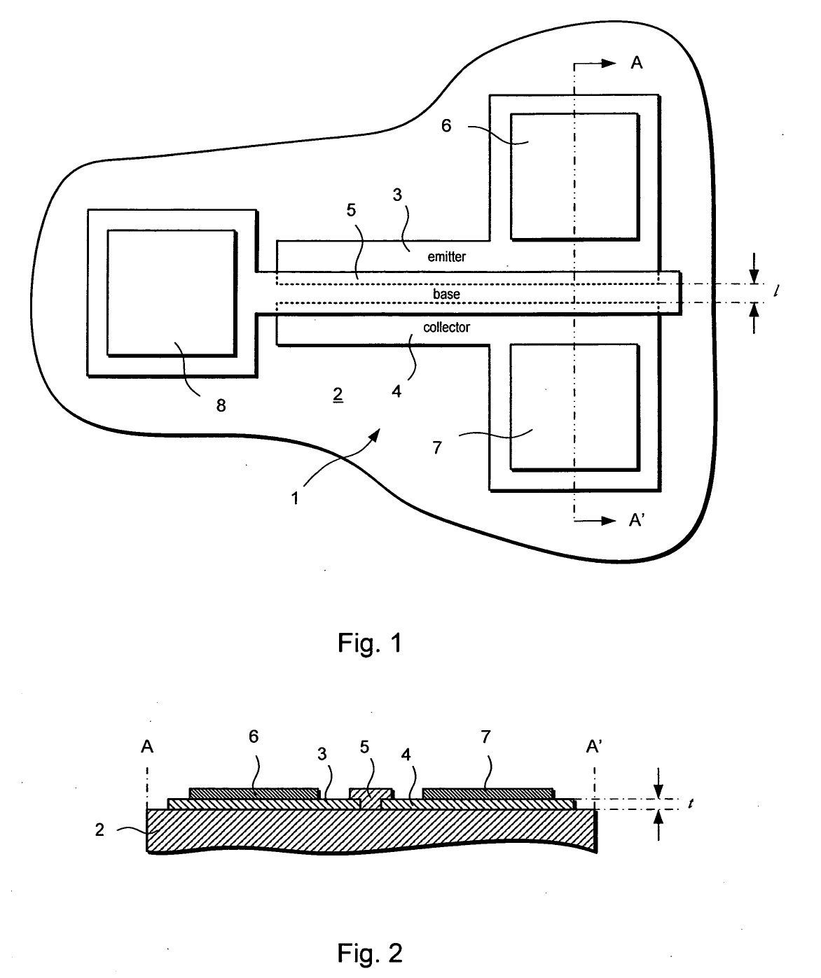

Referring to FIGS. 1 and 2, a bipolar junction transistor (often referred to as “BJT”) 1 is provided on a glass substrate 2 and includes an n⁺-type polycrystalline silicon emitter and collector regions 3, 4 and a p⁺-type polycrystalline silicon base region 5. Each transistor region 3, 4, 5 has a respective aluminium contact 6, 7, 8.

As shown in FIG. 1, the length, l, of the base region 5 between the emitter and collector regions 3, 4 is 1 μm. However, the base region 5 may be longer (e.g. l<5 μm) or shorter (e.g. l<1 μm). The width of the emitter and collector regions 3, 4 is about 10 μm. However, regions 3, 4 may be wider or narrower (e.g. <10 μm). As shown in FIG. 2, the thickness, t, of the emitter and collector regions 3, 4 is about 100 nm. The emitter and collector regions 3, 4 may be thicker (e.g. t<200 nm) or shorter (e.g. t<100 nm). The thickness of the base region 5 is also about 100 nm. Dimensions of the regions 3, 4, 5 can be adjusted to suit a particular requirement, e.g. “on” current, and can be found by routine experiment.

The emitter and collector regions 3, 4 are doped with phosphorous (P) to a concentration of about 1×10¹⁸ cm⁻³. The base region 5 is doped with boron (B) to a concentration of about 1×10¹⁸ cm⁻³. However, different p- and n-type impurities and/or different doping concentrations (e.g. up to 1×10²⁰ cm⁻³ or higher) may be used.

As will be described in more detail hereinafter, the bipolar junction transistor 1 is fabricated according to some embodiments of the present invention using printable materials. An inorganic semiconductor is printed (e.g. by inkjet) and cured (e.g. by laser crystallization) to provide a semiconductor having a sufficiently high mobility (e.g. >100 cm²V⁻¹ s⁻¹) to form a bipolar junction transistor suitable for radio frequency applications. In the embodiments hereinafter described, the bipolar junction transistors are based on silicon. However, other semiconductors, such as silicon-germanium or gallium arsenide, may be used.

Herein, a material borne (e.g. suspended or dissolved) in a carrier (e.g. a liquid or a wax) and which is suitable for printing is referred to as “ink”. For example, a carrier-borne inorganic semiconductor is referred to as an “inorganic semiconductor ink”.

### Fabrication Process

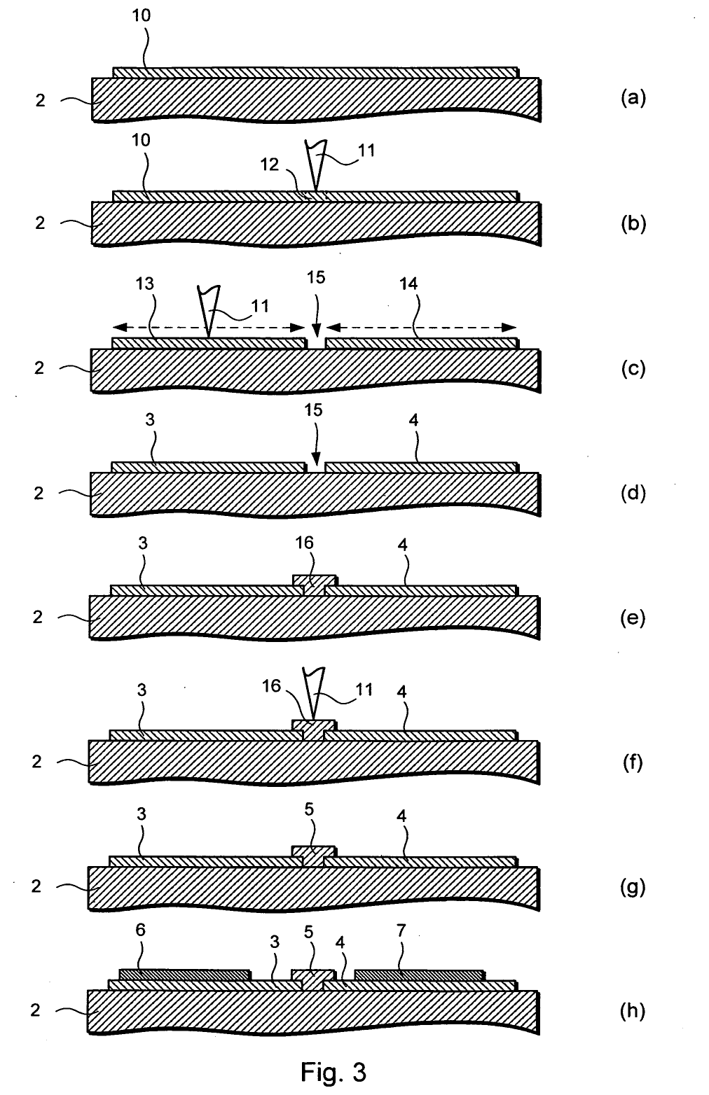

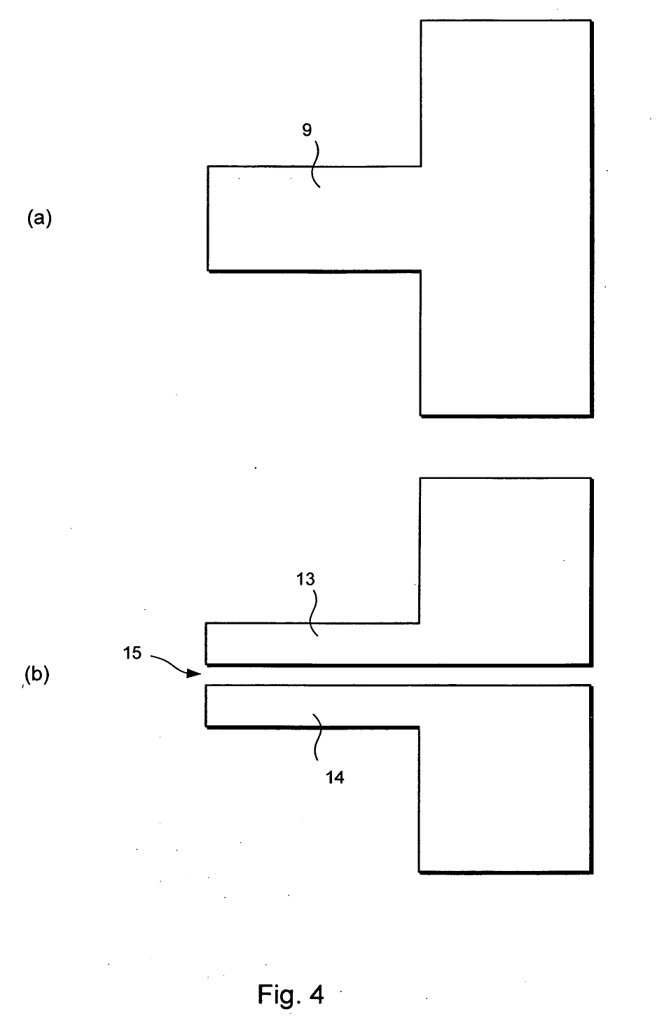

Referring to FIGS. 3a to 3f and FIGS. 4a and 4b, a method of fabricating the bipolar junction transistor 1 (FIG. 1) will now be described in more detail.

A region 10 of silicon ink carrying nanoparticles of n⁺ silicon is applied to the glass substrate 2 by inkjet printing. In some embodiments, a flexible substrate may be used and so a sheet of the substrate may be paid out from a roll (not shown). In this example, the silicon ink takes the form of a suspension in which nanometre-sized (e.g. ˜5 nm) crystals of n⁺ silicon are suspended in tetradecane. However, the silicon ink need not be suspension. Furthermore, the silicon need not be crystalline and may be, instead, amorphous.

The viscosity of the silicon ink is such that a uniform layer of silicon ink having a thickness of about 100 nm is deposited.

Referring in particular to FIGS. 3b and 4b, the silicon ink region 10 is trimmed using a laser beam 11 to remove a strip 12 between first and second silicon ink regions 13, 14 so as to leave a gap 15 having a length, l, of 1 μm.

For trimming, the laser beam 11 delivers higher power than used during curing (described hereinafter), for example by operating at a higher power density, smaller beam size and/or longer pulse duration, so as to ablate material. The laser beam 11 may operate under a gaseous atmosphere such that exposed regions react with the surrounding gas to form gaseous reaction products which can be extracted. A different laser source to that used for curing, e.g. operating at a different wavelength, may be used.

The laser beam 11 is pulsed and pulses have a duration of the order of 1-100 μs. The laser beam 11 has a line width of about 1 μm.

The first and second n⁺ silicon ink regions 13, 14 are cured using a pulsed laser beam 11 which rapidly heats the silicon ink regions 13, 14 to a temperature (e.g. >350° C.) above which the silicon nanoparticles melt. The melted silicon nanoparticles cool and solidify to form n⁺ polycrystalline silicon emitter and collector regions 3, 4.

Laser crystallization is described in “Ultrafast laser-induced crystallization of amorphous silicon filmes” by T. Y. Choi, D. J. Hwang & C. P. Grigoropoulous, Optical Engineering, volume 42, page 3383 (2003) and in “Laser crystallization of silicon for high-performance thin-film transistors” by R. Dassow et al., Semiconductor Science and Technology, volume 15, page L31 (2000) which are incorporated herein by reference.

A barrier layer (not shown) formed of a wax may be provided between the first and second n⁺ silicon ink regions 13, 14, in the gap 15, before curing these regions. The barrier layer (not shown) may be vaporized during curing. The barrier layer (not shown) helps to prevent ink from flowing into the gap 15 during curing.

Referring in particular to FIG. 3e, a region 16 of silicon ink carrying nanoparticles of p⁺ silicon is applied in the gap 15 and which overlaps onto the n⁺ polycrystalline silicon emitter and collector regions 3, 4 by inkjet printing.

The p-type silicon ink region 16 is cured using scanning a pulsed laser beam 11 over it. Silicon nanoparticles in the p⁺-type silicon ink region 16 melt, cool and crystallise to form p⁺ polycrystalline silicon base region 5.

Aluminium regions 6, 7, 8 (FIG. 1) are provided over portions of the emitter, collector and base regions 3, 4, 5. The process of providing the aluminium regions 6, 7, 8 includes printing aluminium ink (not shown) carrying aluminium nanoparticles and laser curing.

### Fabrication Apparatus

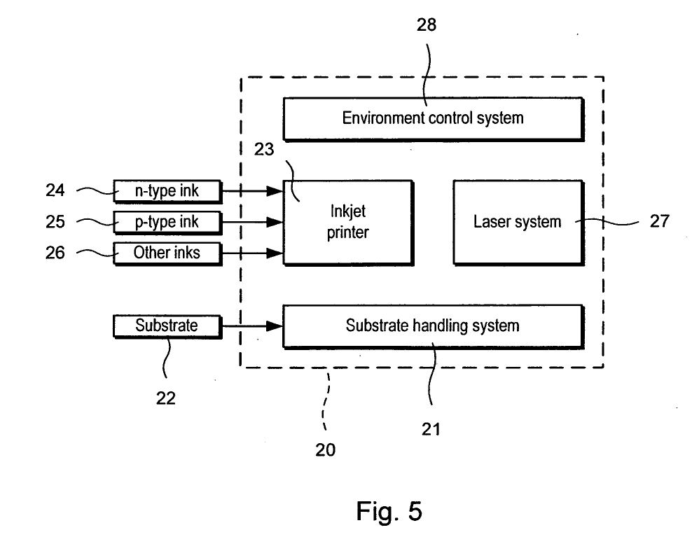

Referring to FIG. 5, apparatus 20 for fabricating the bipolar junction transistor 1 (FIG. 1) is shown.

The apparatus 20 includes a substrate handling system 21. In some embodiments, the substrate handling system 21 is arranged to support a series of separate sheets 22. In other embodiments, the substrate handling system 21 is arranged to handle a continuous sheet.

The apparatus 20 also includes an inkjet printer 23 for applying n⁺ and p⁺ silicon inks 24, 25 and aluminium ink 26.

The silicon inks 24, 25 are prepared by adding n⁺ or p⁺ silicon nanoparticles into a carrier. In certain embodiments, the silicon nanoparticles are prepared by electrochemically etching an n⁺ or p⁺ single crystal wafer (not shown) in hydrofluoric acid and hydrogen peroxide to leave a porous wafer (not shown) and to break up the porous wafer into a collection of nanometre-sized particles using an ultrasound bath. The nanoparticles of a given size or within a given size range are separated and added to the carrier.

The apparatus 20 also includes a high-power laser system 27, such as a Ti:Sapphire laser. The laser system 27 is arranged to provide a pulsed beam having a power density of >10⁶ Wcm⁻².

In some embodiments, a separate inkjet printer may be provided for each ink so as to avoid contamination. Also, a separate laser system may also be provided for each printing stage. As will be explained in more detail later, printed ink patterns may be trimmed using the laser system 27. Alternatively, a separate laser system may be provided for trimming or each trimming stage.

The apparatus 20 also includes an environment control system 28. The environment control system 28 provides an inert atmosphere (e.g. nitrogen gas) under which the inks 24, 25, 26 can be crystallized or cured. In some embodiments, the environment control system 28 may include a vacuum system for allowing the inks 24, 25, 26 to be crystallized or cured under a vacuum.

### Alternative Fabrication Processes

The n⁺ or p⁺ silicon nanoparticles may have respective different types of coating, e.g. polymers, such that when an electric field is applied to a liquid carrier carrying both n⁺ or p⁺ silicon nanoparticles, the two types of nanoparticles separate and drift in opposing directions. Thus, a carrier carrying both n⁺ or p⁺ silicon nanoparticles can be printed and exposed to an electric field to form different regions of the transistor. During curing, the liquid carrier and the coating vaporise and the nanoparticles melt. The nanoparticles may be applied in vapour form, e.g. sprayed onto the surface during which an electric field is applied so as control which charge-carrier type of semiconductor lands on the surface.

Referring again to FIGS. 3b and 4b, in some embodiments, the first and second silicon ink regions 13, 14 are defined by depositing a single block of ink 9 and cutting a strip 12 between the regions 13, 14.

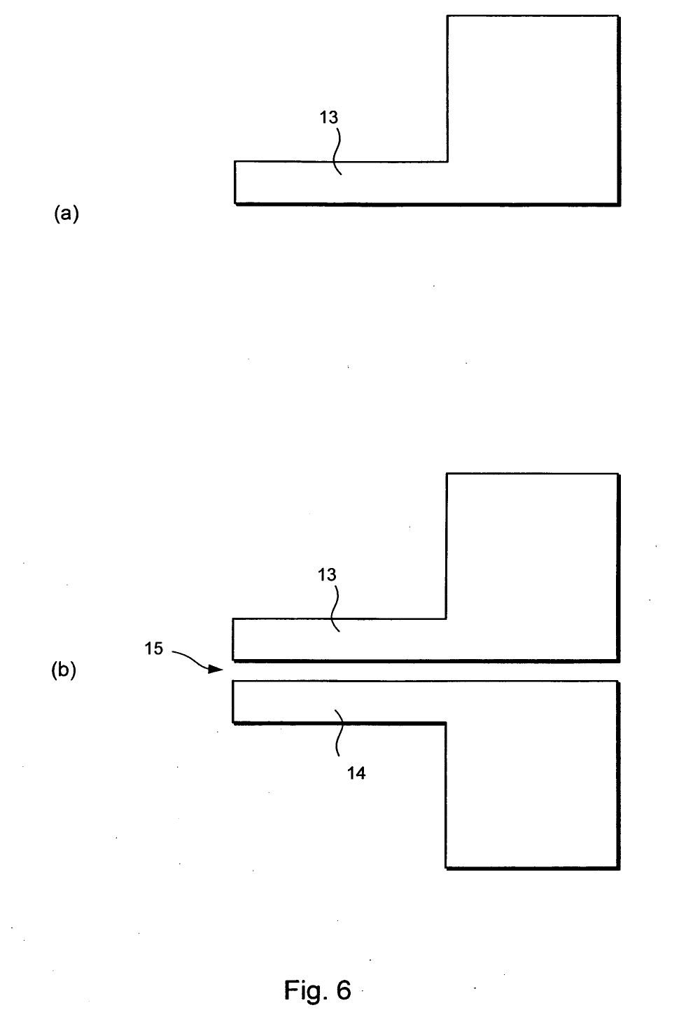

Referring to FIGS. 6a and 6b, in other embodiments, the first and second silicon ink regions 13, 14 are successively printed as two, separate regions 13, 14 and cured before an overlying base ink region (not shown) is printed. However, the regions 13, 14 may be printed substantially at the same time, e.g. by scanning a print head (not shown) in a line over the first and second regions 13, 14, returning and scanning another line over the first and second regions 13, 14.

The inks and or the surface to which they are applied may be chosen or adapted such that each region of ink 13, 14 coalesces separately or draws away from each other, rather then merge, when applied and/or cured. For example, inks having suitably high surface tension and/or van der Waals forces may be chosen. Additionally or alternatively, the surface material may be chosen or treated so as to be hydrophobic to repel the ink or hydrophilic (i.e. “hygroscopic”) to attract the ink, as necessary. The surface may be patterned to leave selective areas which are hydrophobic (e.g. to form the gap) and/or hydrophilic (e.g. to form the regions of ink).

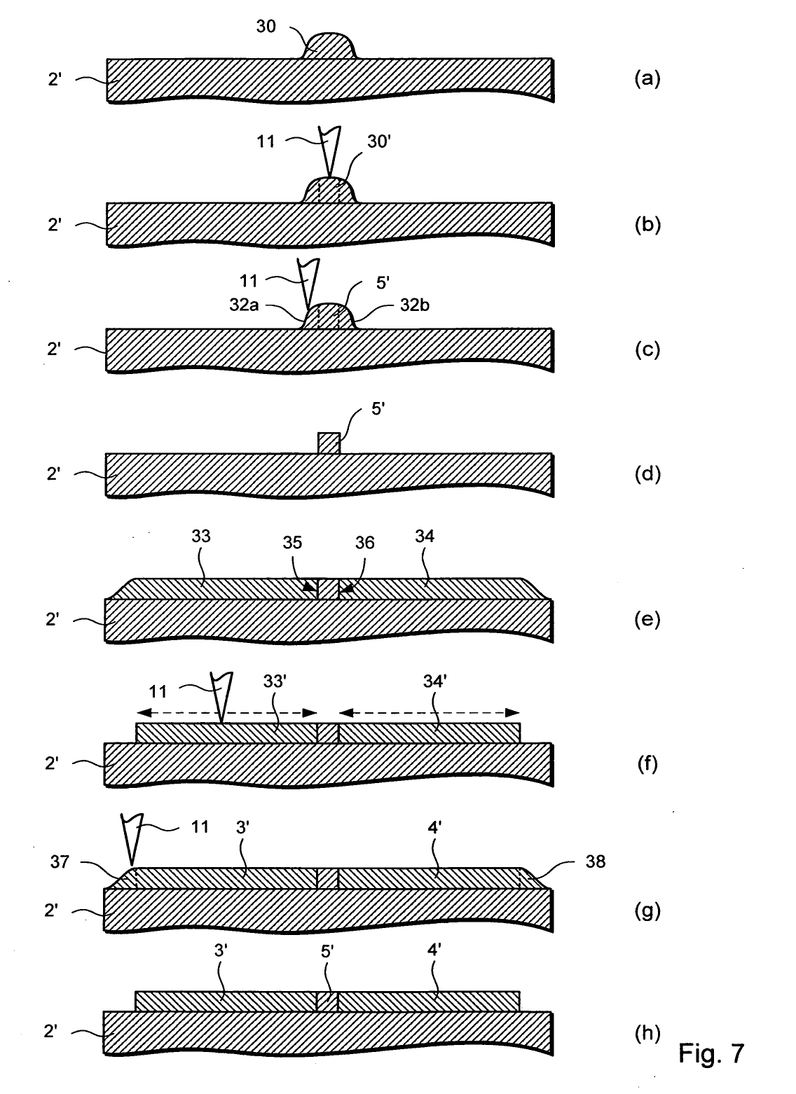

Referring to FIGS. 7a to 7h, another method of fabricating a bipolar junction transistor will now be described. The method is similar to that described earlier and the transistor is set out in a similar way to the bipolar junction transistor 1 shown in FIG. 1. However, in the following method, printed ink patterns are trimmed using the laser system 27 (FIG. 5).

A region 30 of p⁺ silicon ink is applied to the glass substrate 2′ by inkjet printing, in the same way as described earlier.

Referring in particular to FIG. 7b, the p⁺ silicon ink region 30 is cured using a laser beam 11. As described hereinbefore, silicon nanoparticles in a central p⁺ region 30′ melt, cool and crystallise to form a p⁺ polycrystalline silicon base region 5′.

Edges 32a, 32b either side of the p⁺ polycrystalline silicon base region 5′ are removed using laser beam 11. If the ink within the edges 32a, 32b are uncured or only partially-cured (i.e. the silicon has not crystallized), then the edges 32a, 32b may be removed by washing, e.g. in a liquid, and/or by selectively etching.

Referring in particular to FIG. 7e, first and second n⁺ silicon ink regions 33, 34 are applied by inkjet printing. The ink flows so that the n⁺ silicon ink regions 33, 34 form abutting, non-overlapping interfaces 35, 36 with the base region 5′.

Referring in particular to FIG. 7f, core n⁺ silicon ink regions 33′, 34′ of the n⁺ silicon ink regions 33, 34 are cured using a laser beam 11 to form n⁺ polycrystalline silicon emitter and collector regions 3′, 4′.

Edges 37, 38 of the n⁺ polycrystalline silicon emitter and collector regions 3′, 4′ are removed, for example using laser beam 11.

Aluminium contacts (not shown) are provided in a similar way to that described earlier.

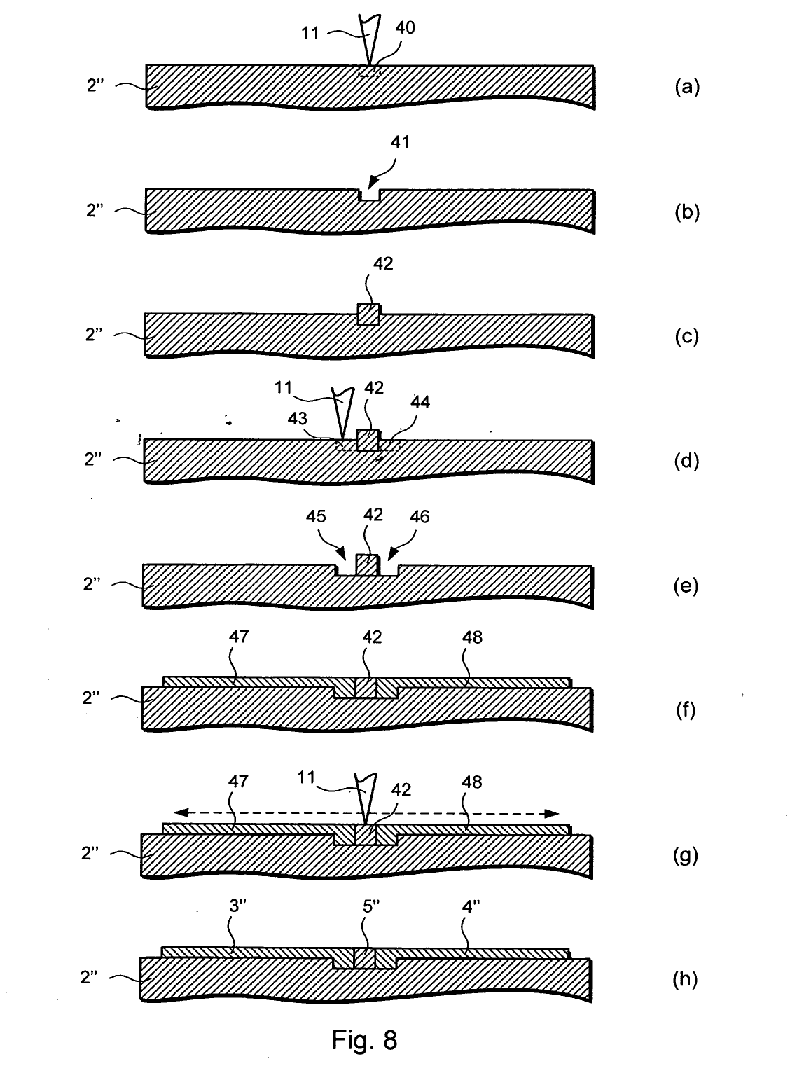

Referring to FIGS. 8a to 8h, yet another method of fabricating a bipolar junction transistor will now be described. The method is similar to that described earlier and the transistor is set out in a similar way to the bipolar junction transistor 1 shown in FIG. 1. However, in the following method, a substrate 2″ is etched using the laser system 27 (FIG. 5).

A strip 40 of the substrate 2″ is etched using laser beam 11 to leave a trench 41.

Referring in particular to FIG. 8c, the trench 41 is filled with p⁺-type silicon ink to form a region 42 of the p⁺ type silicon ink.

Referring in particular to FIGS. 8d and 8e, further strips 43, 44, either side of the p⁺ type silicon ink region 42, are etched using laser beam 11 to leave further trenches 45, 46.

The further trenches 45, 46 are filled with n⁺ silicon ink to form regions 47, 48 of the n⁺ silicon ink.

Referring in particular to FIGS. 8g and 8h, the ink regions 42, 47, 48 are cured using laser beam 11. Silicon nanoparticles in the n⁺- and p⁺-type regions 42, 47, 48 melt, cool and crystallise to form n- and p-type polycrystalline silicon regions 3″, 4″, 5″.

### Alternative Device Structures

The fabrication processes hereinbefore described can be used to fabricate different types of bipolar transistors, as will now be described.

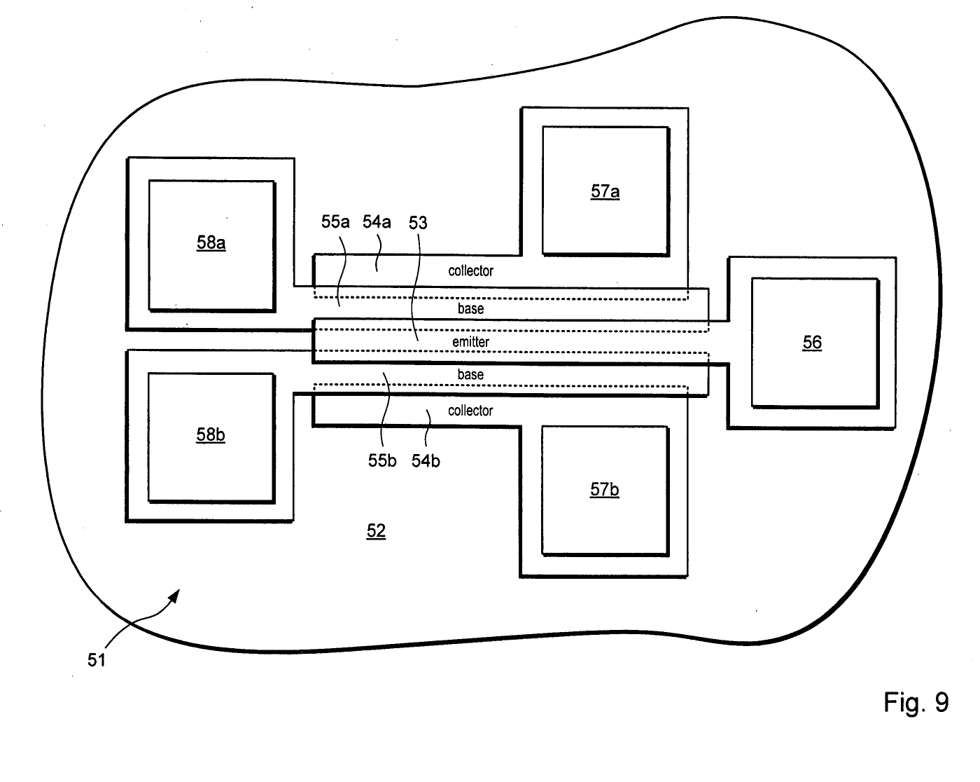

Referring to FIG. 9, a bipolar differential pair device 51 is provided on a glass substrate 52 and includes an n⁺ polycrystalline silicon emitter region 53, first and second n⁺ polycrystalline silicon collector regions 54a, 54b and first and second a p⁺ polycrystalline silicon base regions 55a, 55b. Each transistor region 53, 54a, 54b, 55a, 55b has a respective aluminium contact 56, 57a, 57b, 58a, 58b.

To fabricate the bipolar differential pair device 51, two regions (not shown) of n⁺ silicon ink for defining the collector regions 54a, 54b are printed and then cured. A single region (not shown) of p⁺ silicon ink for defining the base regions are printed, cut to form two regions (not shown) and then the two p⁺ silicon ink regions are cured. Finally, a single region of n⁺ silicon ink for defining the emitter region 53 is printed and then cured.

In a similar way to that described earlier, the bipolar differential pair device 51 may be fabricated in fewer steps by using inks and or a surface such that each region of ink coalesces separately or draws away from each other, rather then merge, when applied and/or cured.

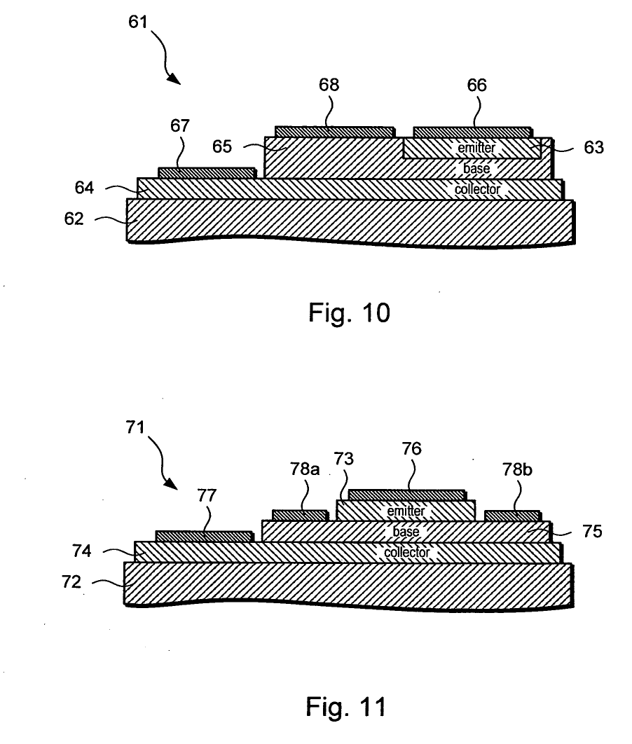

Referring to FIG. 10, a bipolar junction transistor 61 having a stacked structure is shown. The bipolar junction transistor 61 can be fabricated using the processes hereinbefore described. The transistor 61 is fabricated on a glass substrate 62 and includes n⁺ polycrystalline silicon emitter and collector regions 63, 64 and a p⁺ polycrystalline silicon base region 65. Each transistor region 63, 64, 65 has a respective aluminium contact 66, 67, 68.

To fabricate the transistor 61, a region (not shown) of n⁺ silicon ink for defining the collector region 64 is printed on the substrate 62 and then cured. A region (not shown) of p⁺ silicon ink for defining the base region is printed over the collector region 64 and cured. A recess can be laser cut in the base region 65 and filled with n⁺ silicon ink for defining the emitter region 63 and then cured. Thus, a structure similar to a diffusion well can be fabricated.

Referring to FIG. 11, a hetero bipolar transistor 71 is shown. The bipolar junction transistor 71 can be fabricated using the processes hereinbefore described. The transistor 71 is fabricated on a glass substrate 72 and includes n⁺ polycrystalline silicon emitter and collector regions 73, 74 and a p⁺ polycrystalline silicon base region 75. The emitter and collector regions 73, 74 each have a respective aluminium contact 76, 77. The base region 75 has two contacts 78a, 78b.

To fabricate the transistor 71, a region (not shown) of n⁺ silicon ink for defining the collector region 74 is printed on the substrate 72 and then cured. A region (not shown) of p⁺ silicon ink for defining the base region is printed over the collector region 74 and cured. A region (not shown) of n⁺ silicon ink for defining the emitter region 73 is printed over the base region 75 and then cured.

It will be appreciated that many modifications may be made to the embodiments hereinbefore described.

The bipolar junction transistor need not be a n-p-n transistor, but may be a p-n-p transistor. Different substrates can be used. For example, the substrate may be a metal or metal alloy, such as stainless steel, and may be covered by an electrically insulating material such as silicon dioxide. The substrate may be a plastic, such as polyethylene naphthalate (PEN), polyethylene terephthalate (PET) or polyimide (such as Kapton™ foil). Different printing methods may be used, such as gravure, offset printing or nanoimprint lithography. The carrier-borne semiconductor need not be crystalline, but may be polycrystalline or amorphous. The carrier-borne semiconductor need not be in the form of a suspension. For example, the carrier-borne semiconductor may be dissolved in a solvent. The carrier may be isopropyl alcohol or a liquid wax. To achieve doping, a semiconductor ink may comprise nanoparticles of intrinsic semiconductor and nanoparticles of dopant. Alternatively, the dopant may be provided by the carrier. More than one layer of ink may be applied to achieve thick layers. The thickness of ink may be less than or equal to 200 nm, less than or equal to 100 nm or less than or equal to 50 nm. Particles of semiconductor material may have a diameter less than 500 nm, less than 200 nm, less than 100 nm, less than 50 nm, less than 20 nm, less than 10 nm or less than 5 nm. An adhesion layer may be applied to the substrate and/or surface of a patterned layer to aid adhesion of an overlying ink layer. Laser crystallization need not be used. Instead, a furnace of oven can be used. A buffer layer may be provided between the substrate and printed layers, e.g. to provide a heat sink so as to protect the substrate and/or to provide a chemical (e.g. diffusion) barrier to help prevent contamination. After curing, the semiconductor need not be polycrystalline, but may be, for example, amorphous. The semiconductor device may be a field effect transistor. The semiconductor device may be a logic device and/or a memory device. The inorganic semiconductor material may be a binary, e.g. GaAs, or ternary semiconductor, AlGaAs. The inorganic semiconductor may be a IV-IV semiconductor, such as SiGe or SiC, a III-V semiconductor, such as GaAs or GaN, or a II-VI semiconductor CeTe.

It should be realised that the foregoing examples should not be construed as limiting. Other variations and modifications will be apparent to persons skilled in the art upon reading the present application. Such variations and modifications extend to features already known in the field, which are suitable for replacing the features described herein, and all functionally equivalent features thereof. Moreover, the disclosure of the present application should be understood to include any novel features or any novel combination of features either explicitly or implicitly disclosed herein or any generalisation thereof and during the prosecution of the present application or of any application derived therefrom, new claims may be formulated to cover any such features and/or combination of such features.

While there have been shown and described and pointed out fundamental novel features of the invention as applied to preferred embodiments thereof, it will be understood that various omissions and substitutions and changes in the form and details of the devices and methods described may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto. Furthermore, in the claims means-plus-function clauses are intended to cover the structures described herein as performing the recited function and not only structural equivalents, but also equivalent structures. Thus although a nail and a screw may not be structural equivalents in that a nail employs a cylindrical surface to secure wooden parts together, whereas a screw employs a helical surface, in the environment of fastening wooden parts, a nail and a screw may be equivalent structures.

What is claimed is:

1. A method comprising:
providing a substrate; and
forming a bipolar transistor on the substrate;
wherein forming the bipolar transistor includes printing at least one region of inorganic semiconductor on the substrate.

2. A method according to claim 1, further comprising:
heating the region of inorganic semiconductor and allowing said region to cool so that at least a portion of the inorganic semiconductor region crystallizes.

3. A method according to claim 2, wherein heating the region of inorganic semiconductor comprises scanning a laser beam over said region of inorganic semiconductor.

4. A method according to claim 1, further comprising removing a portion of the region of inorganic semiconductor.

5. A method according to claim 4, wherein removing the portion of the region of inorganic semiconductor comprises scanning a laser beam over said inorganic semiconductor.

6. A method according to claim 1, wherein forming the semiconductor device comprises printing a first region of an inorganic semiconductor of a first conductivity type and printing a second region of an inorganic semiconductor of a second, different conductivity type.

7. A method according to claim 1, wherein the substrate comprises glass.

8. A method according to claim 1, wherein the substrate comprises plastic.

9. A method according to claim 1, further comprising processing the substrate before printing the at least one region of inorganic semiconductor on the substrate.

10. A method according to claim 9, wherein processing the substrate comprises etching the substrate.

11. A method according to claim 9, wherein processing the substrate comprises providing a layer on the substrate and printing the at least one region of inorganic semiconductor over at least a portion of the layer.

12. A method according to claim 1, wherein the inorganic semiconductor comprises silicon.

13. A method comprising:
providing a substrate; and
forming a semiconductor device on the substrate;
wherein forming the semiconductor device includes:
printing at least one region of inorganic semiconductor on the substrate; and
heating the region of inorganic semiconductor and allowing said region to cool so that at least a portion of the inorganic semiconductor region crystallizes.

14. A method according to claim 13, wherein heating the region of inorganic semiconductor comprises scanning a laser beam over said region of inorganic semiconductor.

15. A device comprising:
a bipolar transistor having at least one region comprising an inorganic semiconductor, said region formed by printing.

16. A device according to claim 15, wherein the inorganic semiconductor comprises silicon.

17. A device according to claim 15, wherein the bipolar transistor is formed on a substrate comprising glass.

18. A device according to claim 15, wherein the bipolar transistor is formed on a substrate comprising plastic.

19. A device according to claim 15, comprising a substrate having a trench and the at least one region comprising the inorganic semiconductor is disposed within the trench.

20. A device according to claim 15, wherein the bipolar transistor comprises an emitter, a base and a collector region, and each region comprises an inorganic semiconductor formed by printing.

21. A device comprising:
means for providing a bipolar transistor having at least one region comprising an inorganic semiconductor; and
means for forming said region by printing.

22. A device according to claim 21, wherein the inorganic semiconductor comprises silicon.
